(19) United States
(12) Patent Application Publication
(10) Pub. No.: US 2002/0173121 A1
(43) Pub. Date: Nov. 21, 2002

(54) Process for the production of electric parts

(75) Inventors: Kazuyuki Ohya, Tokyo (JP); Norio Sayama, Tokyo (JP); Kazuhiro Otsu, Tokyo (JP)

Correspondence Address: SUGHRUE MION, PLLC, 2100 Pennsylvania Avenue, NW, Washington, DC, 20037-3213, US

(73) Assignee: MITSUBISHI GAS CHEMICAL COMPANY, INC.

(21) Appl. No.: 10/144,022

(22) Filed: May 14, 2002

(30) Foreign Application Priority Data
May 14, 2001 (JP) 142915/01

(51) Int. Cl. H01L 21/30; H01L 21/46

(52) U.S. Cl. 438/459

(57) ABSTRACT

A process for the production of electric parts, comprising

performing the step of forming circuit parts on one surface (surface A) of a semiconductor substrate, the step including the introduction of impurities,

bonding the surface A of the semiconductor substrate to a holding substrate (BP),

performing a back surface treatment step essentially including a polishing of the exposed surface (surface B) of the semiconductor substrate to a thickness of 100 μm or less to obtain an electric-parts-formed thinned substrate, and

separating the thinned substrate from the holding substrate (BP),

wherein an organic protective coat (RC) is used as a protective coat for the circuit parts on the surface A and the bonding was carried out with the organic protective coat.

### FIELD OF THE INVENTION

The present invention relates to a process for the production of thinned electric parts. Specifically, a circuit protective coat of a semiconductor substrate is directly used as an adhesion layer to a holding substrate. In particular, the process enables a separation even when the separation is extremely difficult, for example when an adhesive strength is strengthened by a treatment step essentially requiring a high-temperature step or other treatment steps.

### BACKGROUND OF THE INVENTION

In recent years, electronic devices have been desired to be decreased in thickness or in weight. Electric devices are decreasing in thickness further and further, as is typically found in a portable telephone or an IC card. From the viewpoint of a speed-up or a decrease in electric power consumption, it is required to decrease the thickness of a semiconductor.

When electric circuits are formed on only one surface of a semiconductor wafer or a ceramic substrate which has been already thinned, warps or distortions occur due to a thermal expansion coefficient difference of approximately 5˜15×10⁻⁶K⁻¹ between a material for the formation of the circuits, particularly a metal such as aluminum, copper or gold, and the silicon wafer or the ceramic substrate. Due to the occurrence of warps or distortions, it becomes impossible to form circuits on its back surface and furthermore it becomes also impossible to carry out even all steps of the front surface in some cases. For this reason, it is substantially impossible to use a substrate which has been already thinned.

Thus, conventionally, when electric circuits are formed on only one surface of a substrate, there is adopted a method in which an electric-circuits-forming step essentially requiring a high temperature is performed mainly on one surface (front surface) of a substrate having a thickness, generally at least 200 μm, sufficient for retaining the shape thereof, then the front surface is bonded to a holding substrate to protect the front surface, and the opposite surface (back surface) is polished to thin the substrate.

Conventionally, as a thinning method, there is proposed a fixation method using a wax or a tape.

As a fixitation method using a wax, there is proposed a method in which a wax is applied on a dummy wafer (holding substrate) under heat, a wafer is bonded to the dummy wafer, the wafer is ground and further polished and then the wafer is separated from the dummy wafer by melting the wax under heat and then slipping the wafer sideways or by cooling the wax and then breaking the wax which has become fragile by means of an impact breakdown. However, the wax fixation has problems of thickness accuracy, parallelism and flatness.

As a tape fixation method, there is a method in which a back-grinding tape is affixed to a front surface of a substrate and the opposite surface of the substrate is polished to thin the substrate.

When it is required to form a metal thin layer on the back surface of a thinned wafer or a thinned substrate, generally, there is required a high-temperature treatment step at a temperature of from 250 to 450° C. for from 30 minutes to 1 hour, which high-temperature treatment includes, for example, a pretreatment with hydrofluoric acid, nitric acid or the like, a deposition of metal such as aluminum or gold, and a calcination treatment thereof.

However, it is impossible to carry out these steps under the state where the thinned wafer or the thinned substrate is bonded to the holding substrate with a wax or a back-grinding tape. In the method using a wax or a tape for thinning, after a wafer or substrate is thinned, it is separated from the holding substrate and then subjected to a high-temperature treatment step. A thinned wafer is very fragile. Further, since semiconductor circuits different in thermal expansion coefficient from a substrate exist on one surface, a defective fraction considerably increases because of distortion or breakage. Further, when the thickness is thin or approximately 50 μm, it is difficult to carry out a high-temperature treatment step.

If electric circuits can be efficiently formed on a thinned semiconductor substrate or ceramic substrate having a large work size, electric parts having a decreased thickness, a high speed and a decreased electric power consumption can be practically produced.

Thus, the present inventors have proposed a method in which a semiconductor substrate is bonded to a holding substrate, the semiconductor substrate is thinned, the thinned semiconductor substrate bonded to the holding substrate is directly subjected to a high temperature treatment step or other steps and, after the completion of these steps, the semiconductor substrate is separated from the holding substrate by using water or the like (JP-A-2001-77304, Japanese Patent Application Nos. 2001-30746, 2000-401077, 2000-401078, etc.).

However, in the above method, when a treatment step at more than 400° C. is present, the separation is substantially impossible. Further, when an organic protective coat is used as a surface protective coat for the semiconductor circuit, it is very difficult in some cases to find a bonding resin composition which has an adhesion reliability sufficient for enduring a back surface processing step and effects an easy separation after the completion of the step even when no high temperature treatment step is present.

### SUMMARY OF THE INVENTION

It is an object of the present invention to provide a method which endures a back-surface treatment step and can perform a separation even when an adhesion is strengthened by a high-temperature treatment step or even when it is difficult to find an easily-separable bonding resin composition.

According to the present invention, there is provided a process for the production of electric parts, comprising

performing the step of forming circuit parts on one surface (surface A) of a semiconductor substrate, the step including the introduction of impurities,

bonding the surface A of the semiconductor substrate to a holding substrate (BP),

performing a back surface treatment step essentially including a polishing of the exposed surface (surface B) of the semiconductor substrate to a thickness of 100 μm or less to obtain an electric-parts-formed thinned substrate, and

separating the thinned substrate from the holding substrate (BP),

wherein an organic protective coat (RC) is used as a protective coat for the circuit parts on the surface A and the bonding was carried out with the organic protective coat.

### DETAILED DESCRIPTION OF THE INVENTION

In the present invention, preferably, the organic protective coat (RC) is formed on at least the entire periphery of the surface A without any gaps.

In the present invention, preferably, the holding substrate (BP) is a product obtained by impregnating an inorganic continuously porous sintered body containing 2 to 35% by volume of continuous pores having an average pore diameter of 0.1 to 10 μm with a heat-resistant resin and curing the impregnated heat-resistant resin.

In the present invention, particularly preferably, the inorganic continuously porous sintered body is selected from the group consisting of aluminum nitride-boron nitride(AlN-h-BN), silicon carbide(SiC), aluminum nitridesilicon carbide-boron nitride(AlN—SiC-h-BN), alumina-boron nitride (Al₂O₃-h-BN), silicon nitride-boron nitride (Si₃N₄-h-BN), zirconium oxide-alumina-boron nitride (ZrO₃—Al₂O₃-h-BN) and alumina-titanium oxide-boron nitride(Al₂O₃—TiO-h-BN).

The constitution of the present invention will be explained hereinafter.

The present invention is characterized in that the organic protective coat (RC), which is a protective coat for circuit parts of the surface A, is directly used as an adhesion layer.

Examples of a material for forming the organic protective coat (RC) include polyimide, a photosensitive polyimide, silicone imide, a photosensitive silicone imide, a fluorine-compound-modified polyimide, a silicone resin, a benzocyclobutene polymer, polyarylene ether, polyquinoline and a perfluorohydrocarbon polymer.

Generally, the above material for forming the organic protective coat (RC) is applied by a spin coating, dried, optionally exposed to light and developed as required, to form a protective coat having a thickness of 0.2 to 10 μm. Further, as another method, for example, there is a method in which the material for forming the organic protective coat (RC) is properly activated by plasma or the like in a pressure-reduced atmosphere and the activated material is deposited while polymerizing at a desired site. For this method, polyparaxylenes may be used.

Further, the holding substrate of the present invention is selected depending upon the condition of a back surface treatment step as required, while the holding substrate of the present invention is required to have high heat resistance and high chemical resistance. Further, it is needed for decreasing a warp after the bonding that the holding substrate has a thermal expansion coefficient near to that of the semiconductor substrate.

Generally, examples of the holding substrate includes inorganic compound-based materials such as aluminum nitride, silicon carbide, silicon nitride, sapphire, alumina, zirconia, wollastonite, amorphous carbon, glassy carbon and a C/C composite with silicon carbide. A silicon wafer can be also used.

Further, there are preferably used those which obtained by impregnating an inorganic continuously porous sintered body having preferably 2 to 35 vol % of continuous pores having an average pore diameter of 0.1 to 10 μm with a heat-resistant resin and curing the impregnated resin. The inorganic continuously porous sintered body includes aluminum nitride-boron nitride(AlN-h-BN), silicon carbide(SiC), aluminum nitride-silicon carbide-boron nitride (AlN—SiC-h-BN), alumina-boron nitride(Al₂O₃-h-BN), silicon nitride-boron nitride (Si₃N₄-h-BN), zirconium oxide-alumina-boron nitride (ZrO₃—Al₂O₃-h-BN), alumina-titanium oxide-boron nitride (Al₂O₃—TiO-h-BN) and amorphous carbon. In particular, inorganic continuously porous sintered bodies disclosed in JP-A-2000-344587 are preferably used.

For improving adhesion and workability in the bonding, the holding substrate preferably has a surface roughness Ra of from 0.1 to 5 μm. When the surface smoothness of the holding substrate is too high, a gaseous body is likely to remain in the central portion of a bonding surface, which deteriorates workability. In this case, a warp or a breakage in some cases occurs. When the surface roughness Ra is larger than 5 μm, the adhesion layer can not absorb the roughness to cause a wrinkle of the adhesion layer or a breakage of the semiconductor substrate in some cases. Further, the surface of the semiconductor substrate to be used should avoid having a surface roughness of more than 5 μm. When such a roughness is essentially required, it is preferred to use a semiconductor substrate of which the surface is smoothed by forming a protection layer for covering the roughness.

As a method for separating the thinned semiconductor substrate of the present invention from the holding substrate, methods disclosed in JP-A-2001-77304 and Japanese Patent Application Nos. 2001-30746, 2000-401077, 2000-401078, etc., can be employed except that an adhesion film is not used.

Furthermore, there can be adopted, as required, a method in which after the semiconductor substrate is cut to respective chip sizes, a separation is promoted to separate the thinned semiconductor substrate to which the adhesion layer is attached from the holding substrate, and a method in which the semiconductor substrate, to which the adhesion layer is attached, is separated from the holding substrate with the thinned semiconductor substrate being held by adsorption and then the adhesion layer is separated by further carrying out a separation-promoting treatment.

The state of the semiconductor circuit formed on the surface (front surface) to be held, for example an aluminum metal corrosion by an aluminum metal exposure, limits the selection of a separation-promoting method in some cases. In such cases, a separation promotion is selected in consideration of a corrosion prevention.

### EXAMPLES

The present invention will be explained concretely with reference to Examples.

### Example 1

A disk of an aluminum nitride-boron nitride continuous porous sintered body which disk had a thickness of 0.625 mm and a diameter of 150.5 mm was surface-treated by the impregnation and pyrolysis of an aluminum compound, the surface-treated disk was impregnated with a ladder silicon resin, the impregnated-resin was cured and the surface of the resultant disk was polished to prepare a holding substrate (to be referred to as “AN-1” hereinafter) having a surface roughness Ra of 0.3 μm, a parallelism of 2 μm and a flatness of 2 μm.

One surface of a silicon wafer having a thickness of 0.625 mm and a diameter of 150.3 mm was sputtered with aluminum and circuits were formed on the above surface. Then a silicone-modified imide resin was applied to the resultant surface with a spin-coater and the applied silicone-modified imide resin was cured under a nitrogen gas atmosphere in a high-temperature inert oven at 250° C. for 1 hour and then at 350° C. for 2 hours, to obtain a silicone wafer (to be referred to as “SW-1” hereinafter) to which the 4 μm-thick silicone-modified imide resin was attached. The silicone wafer “SW-1” was used as a semiconductor substrate.

As a positional aberration-prevention frame, there was prepared a 1.2 mm-thick aluminum alloy plate having a hole having a diameter of 150.6 mm in its central portion.

A 0.4 mm-thick aluminum alloy plate, a ZYLON felt cushion (trade name: ZYLON supplied by Toyobo Co., Ltd., processed by Ichikawa Co., Ltd.) and a 0.4 mm-thick aluminum alloy plate were piled up in this order to prepare a laminated assistant board.

Rightbeforeusingtheholdingsubstrate, the holding substrate was aged under a nitrogen gas atmosphere having an oxygen concentration of 1 ppm or less in a high-temperature inert oven at 350° C. for 1 hour and then at 400° C. for 2 hours, and the holding substrate was cooled to room temperature.

The positional aberration-prevention frame was placed on the laminated assistant board. The holding substrate AN-1 was disposed in the hole of the positional aberration-prevention frame. The silicon wafer SW-1 was disposed on the holding substrate AN-1 in the hole such that the silicone-modified imide resin-attached surface of the silicon wafer SW-1 was brought into contact with the holding substrate AN-1. Then, the positional aberration-prevention frame was placed thereon. The resultant materials were placed between hot plates of an air plunger pressurization type vacuum press.

The atmosphere in the press was reduced to 1 kPa or lower, then, a pressing was carried out at a surface pressure of 0.2 MPa, the temperature was increased up to 330° C. at a rate of 10° C./minute, the above materials between the hot plates were maintained at 330° C. for 10 minutes, the pressure was opened to atmosphere, and the materials were allowed to cool, whereby the silicon wafer was bonded to the holding substrate.

The holding substrate side of the bonded wafer/holding substrate was mounted on an adsorption board of a horizontal precision surface grinding machine (supplied by Okamoto Machine Tool Works, Ltd., machine name: GRIND-X SRG-200, each revolution number 300 rpm). Then the wafer/holding substrate was ground using a diamond grinding wheel No. 320 at a processing rate of 20 μm/minute until the thickness of the wafer became 90 μm. Then, it was ground using a diamond grinding wheel No.2,000 until the thickness of the wafer became 82 μm. Finally, the wafer/holding substrate was chemically mechanically polished with a CMP machine (supplied by Okamoto Machine Tool Works, Ltd., machine name: GRIND-X, SPL15T, number of revolutions: 35 rpm, load: 7.0 kg) using colloidal silica until the wafer had a thickness of 80 μm and a surface roughness Ra of 0.02 μm, to obtain a thinned wafer/holding substrate.

The thinned wafer surface was treated by washing with a 5% hydrofluoric acid aqueous solution at 25° C. for 20 minutes, then washed by spraying pure water at 25° C. for 1 minute and dried with hot air at 120° C. for 3 minutes and then at 150° C. for 10 minutes.

The thinned wafer/ holding substrate was placed in a high-temperature inert oven. The temperature was increased from 250° C. to 430° C. under a nitrogen gas atmosphere having an oxygen concentration of 1 ppm or lower over 15 minutes. And the thinned wafer/ holding substrate was allowed to stand therein at 430° C. for 30 minutes. The oven was cooled at a rate of 2° C./minute until the temperature of the oven became 50° C. The thinned wafer/holding substrate was taken out from the oven. The thinned wafer/holding substrate was allowed to cool to room temperature.

Further, the thinned wafer/holding substrate was checked for warps on a surface plate. The amount of the warp was 120 μm. Further, there was found no separation between the thinned silicone wafer and the holding substrate.

The 80 μm-thick thinned wafer/holding substrate was set in a holder in a quartz container filled with pure water having 80° C. and left in the pure water. 66 minutes later, the thinned wafer was naturally separated from the holding substrate.

After the separation, the protective coat was still bonded to the thinned wafer.

The holding substrate can be re-used by washing with water and drying.

### Example 2

A disk of an alumina-boron nitride continuous porous sintered body which disk had a thickness of 0.625 mm and a diameter of 125.0 mm was surface-treated by the impregnation and pyrolysis of an aluminum compound, the surface-treated disk was impregnated with a ladder silicon resin, the impregnated-resin was cured and the surface of the resultant disk was polished to obtain a holding substrate (to be referred to as “AL-2” hereinafter) having a surface roughness Ra of 0.4 μm, a parallelism of 2 μm and a flatness of 2 μm.

One surface of a gallium-arsenic wafer (to be referred to as “GAAS” hereinafter) having a thickness of 0.625 mm and a diameter of 100.0 mm was sputtered with gold. Circuits were formed on the above surface. Then, a polyimide resin solution(trade name: Rikacoat EN-20, supplied by New Japan Chemical Co., Ltd, a resin component concentration 20 wt %, N-methyl-2-pyrolidone solvent) was applied to the above surface of the GAAS by a spin-coating. The applied resin solution was naturally dried for a whole day and night. Then, the resultant GAAS was treated by drying at 120° C. for 30 minutes and at 200° C. for 60 minutes, to obtain a GAAS having a 20 μm-thick polyimide coat. The GAAS having a 20 μm-thick polyimide coat was used as a semiconductor substrate.

A hole having a depth of 0.60 mm and a diameter of 125.3 mm was made in an aluminum alloy plate having a thickness of 1.2 mm. A concentric through hole having the same center as that of the above hole and a diameter of 100.6 mm was made inside the above hole, to prepare a positional aberration-prevention frame.

A 0.4 mm-thick aluminum alloy plate, a silicon cushion (trade name: HT1500 RED, supplied by Rogers (USA)) and a 0.4 mm-thick aluminum alloy plate were piled up in this order to obtain a laminated assistant board.

The laminated assistant board was laid down. Then, the holding substrate AL-2 was placed on the laminated assistant board. The GAAS was placed thereon such that the polyimide coat surface of the GAAS was brought into contact with the holding substrate AL-2. The positional aberration-prevention frame was disposed such that the positional aberration-prevention frame surrounded the holding substrate AL-2 and the GAAS. Then, the laminated assistant board was placed on the GAAS surrounded by the positional aberration-prevention frame. The above materials piled up in the above order were placed between hot plates of an air plunger pressurization type vacuum press. An input aperture was closed. The atmosphere in the vacuum press was reduced to 1 kPa or lower. A pressing was carried out at a surface pressure of 0.1 MPa. The temperature was increased up to 240° C. at a rate of 10° C./minute, and the above materials between the hot plates were maintained at 240° C. for 15 minutes. The pressure was opened to atmosphere and then the materials were allowed to cool, whereby the GAAS was bonded to the holding substrate.

The holding substrate side of the bonded GAAS/holding substrate was mounted on an adsorption board of a precision surface grinding machine (each revolution number 300 rpm). The GAAS surface was ground using a diamond grinding wheel #380 at a processing rate of 20 μm/minute until the thickness of the wafer became 70 μm. Then, it was ground using a diamond grinding wheel #1200 until the thickness of the GAAS became 51 μm. Then, the GAAS surface was chemically mechanically polished with a CMP machine using colloidal silica until the GAAS had a thickness of 50 μm and a surface roughness Ra of 0.03 μm, to obtain a thinned GAAS/holding substrate.

The CMP surface of the thinned GAAS was surfacetreated by spraying a 5% hydrofluoric acid aqueous solution at 25° C. for 20 minutes, then washed by spraying pure water at 25° C. for 1 minute, and then dried with hot air at 120° C. for 3 minutes and at 150° C. for 10 minutes.

Then, the thinned GAAS/holding substrate was immersed in pure water at 60° C. for 60 minutes, while the thinned GAAS was not at all separated from the holding substrate.

Then, the thinned GAAS/holding substrate was dried at 120° C. for 15 minutes. Then, the thinned GAAS/holding substrate was placed in an inert oven set at 250° C. The thinned GAAS/holding substrate was allowed to stand under a nitrogen gas atmosphere having an oxygen concentration of 1 ppm or less in the inert oven at 250° C. for 30 minutes. No warps were found in the inert oven. Then, the thinned GAAS/holding substrate was allowed to cool to room temperature. Then, the thinned GAAS/holding substratewas checked forwarps on a surfaceplate, to find no warps. Further, there was found no separation between the thinned GAAS and the holding substrate in the above drying, heating and cooling.

After the above test, the thinned GAAS/holding substrate was set in a holder in a quartz container filled with N-methyl-2-pyrolidone and left in the N-methyl-2-pyrolidone. Approximately 5 hours later, the thinned GAAS was naturally separated from the holding substrate.

After the separation, the protective coat was still bonded to the thinned GAAS.

The holding substrate can be re-used by washing with water, optionally polishing and the like, and then drying.

### EFFECT OF THE INVENTION

In a conventional production process of electric parts, a separation of a semiconductor substrate from a holding substrate has been possible by manual work but its mechanization essential for industrialization have been difficult. According to the process of the production of electric parts, provided by the present invention, the semiconductor substrate can be easily mechanically separated from the holding substrate. Therefore, the production process of electric parts, provided by the present invention, has great significance industrially.

What is claimed is:

1. A process for the production of electric parts, comprising
performing the step of forming circuit parts on one surface (surface A) of a semiconductor substrate, the step including the introduction of impurities,
bonding the surface A of the semiconductor substrate to a holding substrate (BP),
performing a back surface treatment step essentially including a polishing of the exposed surface (surface B) of the semiconductor substrate to a thickness of 100 μm or less to obtain an electric-parts-formed thinned substrate, and
separating the thinned substrate from the holding substrate (BP),
wherein an organic protective coat (RC) is used as a protective coat for the circuit parts on the surface A and the bonding was carried out with the organic protective coat.

2. A process according to claim 1, wherein the organic protective coat (RC) is formed on at least the entire periphery of the surface A without any gaps.

3. A process according to claim 1, wherein the holding substrate (BP) is a product obtained by impregnating an inorganic continuously porous sintered body containing 2 to 35% by volume of continuous pores having an average pore diameter of 0.1 to 10 μm with a heat-resistant resin and curing the impregnated heat-resistant resin.

4. A process according to claim 3, wherein the inorganic continuously porous sintered body is selected from the group consisting of aluminum nitride-boron nitride(AlN-h-BN), silicon carbide (SiC), aluminum nitride-silicon carbide-boron nitride(AlN—SiC-h-BN), alumina-boron nitride (Al₂O₃-h-BN), silicon nitride-boron nitride(Si₃N₄-h-BN), zirconium oxide-alumina-boron nitride (ZrO₃—Al₂O₃-h-BN) and alumina-titanium oxide-boron nitride (Al₂O₃—TiO-h-BN).

5. A process according to claim 1, wherein the bonding surface of the holding substrate (BP) which surface is to be bonded to the organic protective coat (RC) has a surface roughness Ra of 0.1 to 5 μm.
